(19) United States
(12) Patent Application Publication
(10) Pub. No.: US 2019/0027556 A1
(43) Pub. Date: Jan. 24, 2019

(54) SHALLOW TRENCH ISOLATION (STI) GAP FILL

(71) Applicant: GLOBALFOUNDRIES Inc., Grand Cayman (KY)

(72) Inventors: Jiehui Shu, Clifton Park, NY (US); Rishikesh Krishnan, Cohoes, NY (US); Jinping Liu, Ballston Lake, NY (US); Yiheng Xu, Clifton Park, NY (US); Joseph F. Shepard, JR., Poughkeepsie, NY (US)

(21) Appl. No.: 15/656,574

(22) Filed: Jul. 21, 2017

(51) Int. Cl. H01L 29/06; H01L 21/762; H01L 21/02; H01L 21/3105

(52) U.S. Cl. CPC H01L 29/0649; H01L 21/76224; H01L 21/02164; H01L 21/3105; H01L 21/02274; H01L 21/02271; H01L 21/0228

(57) ABSTRACT

A method of forming a shallow trench isolation (STI) for an integrated circuit (IC) structure to mitigate fin bending disclosed. The method may include forming a first insulator layer in a first portion of an opening in a substrate by a bottom-up atomic layer deposition (ALD) process; and forming a second insulator layer on the first insulator layer in a second portion of the opening. The opening may be position between a set of fins in the substrate. The method may further include forming an oxide liner in the opening before the forming the first insulator layer. The second insulator layer may be formed by deposition using a flowable chemical vapor deposition (FCVD) process, high aspect ratio process (HARP), high-density plasma chemical vapor deposition (HDP CVD) process, or any other conventional insulator material deposition process.

### BACKGROUND

The present disclosure relates to semiconductor device fabrication, and more specifically, to shallow trench isolations (STIs) and methods of forming the STIs, including a bottom-up atomic layer deposition (ALD) process.

Conventional integrated circuit (IC) structure formation generally occurs on the surface of a semiconductor substrate, e.g., silicon substrates. During formation of semiconductor devices on the substrate, shallow trench isolations (STIs), i.e., structures including insulating materials, are formed between electrical components to electrically isolate them from one another. For example, in a fin field effect transistor (FinFET) structure, source and drain regions, and the conducting channel therebetween are formed as a vertical silicon fin-like structure. A gate electrode may be formed on the conducting channels of multiple fins to control the flow of electrons between the respective source and drain regions of the fins. To electrically isolate the conducting channels of each fin, STIs may be formed in the substrate between the source and drain regions of adjacent fins.

Referring to the drawings, FIG. 1 shows a cross-sectional view of a portion of a conventional prior art semiconductor structure 100 including STIs 120 formed in substrate 104 isolating fins 102 formed from substrate 104. STIs 120 are conventionally formed by creating a trench, i.e., opening in substrate 104, between electrical components. The trench may be formed, for example, by patterned etching of substrate 104. The trench may then be filled with a liner 106 and STI fill 110,112, e.g., insulating material such as silicon oxide, and processed to form the STI.

Conventionally, STI fill 110,112 may be formed in the trench using a deposition process. One conventional deposition process for filling the trench includes chemical vapor deposition (CVD). Types of CVD include, high-density plasma CVD (HDPCVD or HDP), high aspect-ratio process (HARP) CVD, and flowable CVD (FCVD). The STI fill may be deposited in the trench, for example, by a single deposition process or by a multi-step deposition process combining a variety of CVD methods. Where the STI fill is formed by the multi-step deposition, an intermediate etching step is typically performed between depositions. The example of FIG. 1 shows forming STI fill 110, 112 by a multi-step deposition process. For example, STI fill 110 may be deposited by FCVD. STI fill 110 may be etched to prepare for deposition of STI 112 which may be deposited, for example, by HARP.

Once the insulating material has been deposited in the trench, further processing such as annealing may be applied to the insulating material to achieve desired properties for the STI fill, for example, a desired density. One challenge relative to forming STIs generally arises during annealing when an STI is formed between fins of a FinFET, as described above. Annealing conventional STI fill 110,112 may cause the STI fill material to contract. Consequently, the contraction of the insulating material may exert a force on fins 102, causing them to bend as shown by fins 114 of fins 102 in FIG. 1. For example, where STI fill 110 is formed by conventional FCVD, the fill material may densify to a density of approximately 2.0 grams per cubic centimeter (g/cm³) to approximately 2.5 g/cm³ after annealing. The insulator layer may contract by approximately 10% which may cause the fins to bend by approximately 1.8 nanometers. Additionally, the wet etch rate of an STI formed by conventional techniques may be approximately 35 Å/min in 100:1 dilute hydrofluoric acid (DHF). The bending of the fins may result in shorting of the semiconductor device, and may render it inoperable.

### SUMMARY

A first aspect of the disclosure is directed to a method of forming an integrated circuit (IC) structure, the method including: forming a first insulator layer in a first portion of an opening in a substrate by a bottom-up atomic layer deposition (ALD) process; and forming a second insulator layer on the first insulator layer in a second portion of the opening.

A second aspect of the disclosure includes a method of forming a shallow-trench-isolation (STI) in an integrated circuit (IC) structure, the method including: forming an oxide liner in a trench in a substrate, the trench positioned between a set of fins in the substrate; forming a first oxide layer on the oxide liner in a first portion of the trench by a bottom-up atomic layer deposition (ALD) process; and forming a second oxide layer on the first oxide layer in a second portion of the trench, wherein the second oxide layer covers the set of fins.

A third aspect of the disclosure is related to an integrated circuit (IC) structure, including: a semiconductor substrate including a shallow trench isolation (STI) therein, the STI including a first insulator layer and a second insulator layer thereon, wherein a first density of the first insulator layer is greater than a second density of the second insulator layer.

The foregoing and other features of the disclosure will be apparent from the following more particular description of embodiments of the disclosure.

### BRIEF DESCRIPTION OF THE DRAWINGS

The embodiments of this disclosure will be described in detail, with reference to the following figures, wherein like designations denote like elements, and wherein:

FIG. 1 shows a cross-sectional view of a portion of a conventional semiconductor structure exhibiting fin bending, according to the prior art.

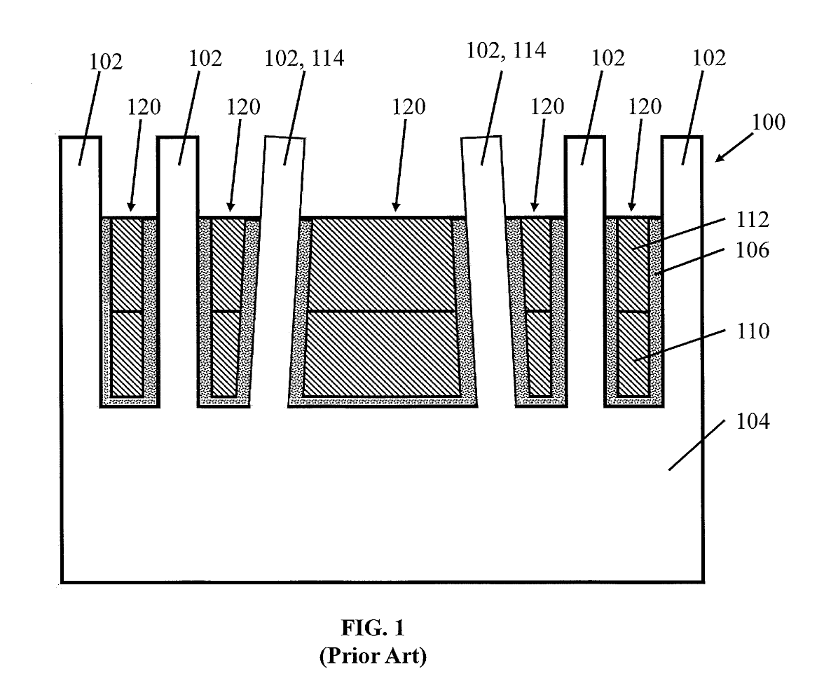

FIG. 2 shows a cross-sectional view of an initial structure for forming a shallow trench isolation (STI), according to embodiments of the disclosure.

FIG. 3 shows forming a first insulator layer on the initial structure of FIG. 2, according to embodiments of the disclosure.

FIG. 4 shows forming a second insulator layer on the first insulator layer of FIG. 3, according to embodiments of the disclosure.

FIG. 5 shows further processing of the first and second insulator layer of the structure of FIG. 4, according to embodiments of the disclosure.

FIG. 6 shows forming STIs by further processing the structure of FIG. 5, according to embodiments of the disclosure.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific embodiments in which the present teachings may be practiced. These embodiments are described in sufficient detail to enable those skilled in the art to practice the present teachings and it is to be understood that other embodiments may be used and that changes may be made without departing from the scope of the present teachings. The following description is, therefore, merely illustrative.

Embodiments of the present disclosure provide a structure and method for forming a shallow trench isolation (STI) for a semiconductor structure. Among other things, the STI may include a first insulator layer formed by a bottom-up atomic layer deposition (ALD) process. Methods of forming the STI may include, among other things, forming the first insulator layer using bottom-up ALD, and forming a second insulator layer on the first insulator layer using a conventional method for forming STI fill. Forming the STI may also include forming the STI between fins in the semiconductor structure. The methods may also include annealing the insulator layers in an oxidizing ambient to densify the insulator layers. Embodiments of the present disclosure may allow for reduced contraction of STI fill material during annealing of the STI. Embodiments of the present disclosure may thereby allow for the mitigation and/or prevention of fin bending during STI formation.

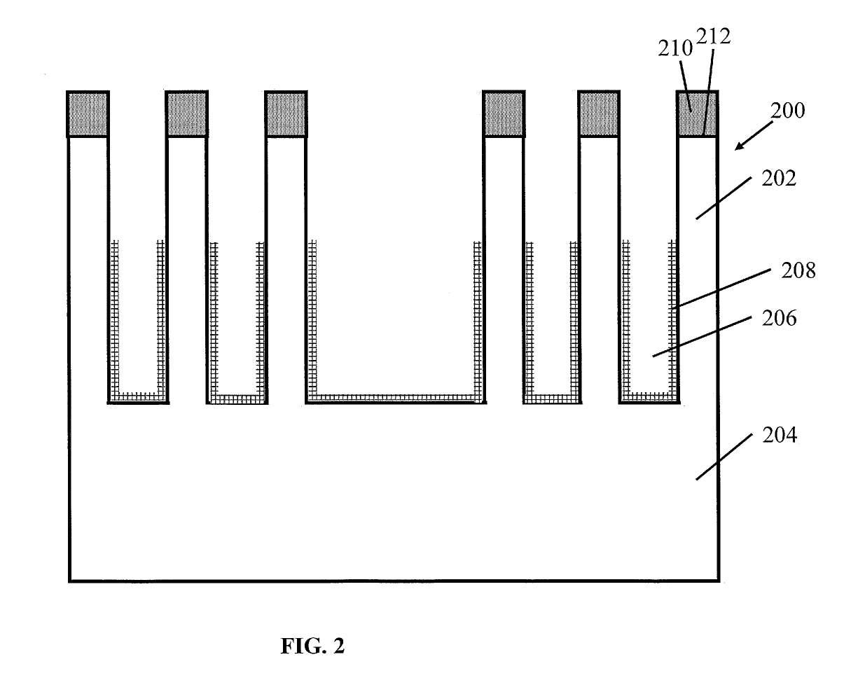

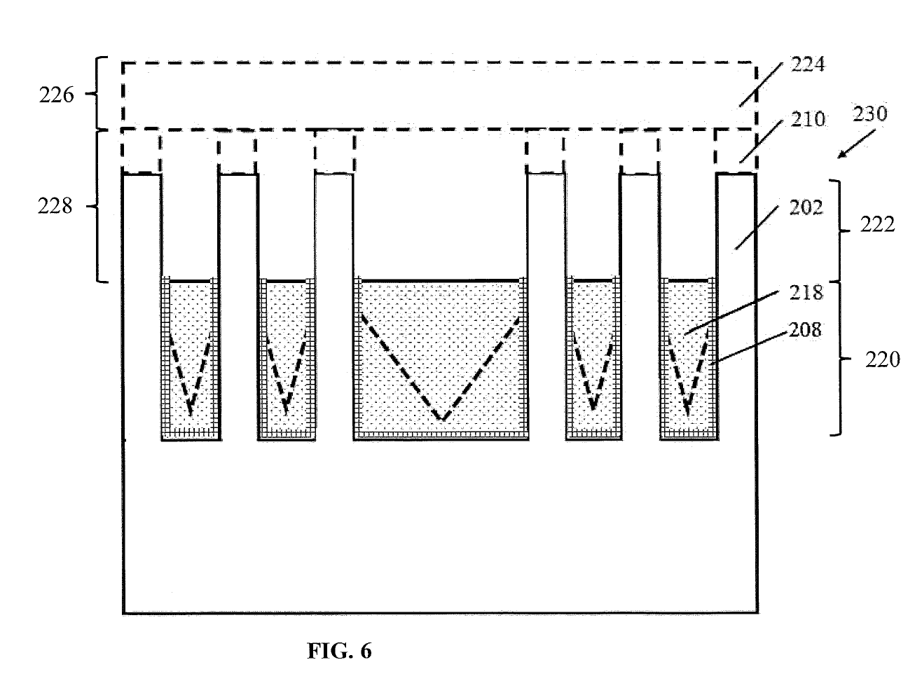

Referring now to the figures, FIG. 2 shows a cross-sectional view of an initial structure 200 for a method of forming shallow trench isolations (STIs) 220 (see FIG. 6), according to embodiments of the disclosure. At this stage, initial structure 200 is provided including a substrate 204 and fins 202. Fins 202 may be isolated from one another by trenches 206 for STIs 220 (see FIG. 6). A liner 208 may be formed in trenches 206 for STIs 220 (see FIG. 6). As shown in the example of FIG. 2, initial structure 200 may include a pad layer 210 on a surface 212 of fins 202, for example, as a barrier layer during formation of STIs 220 (see FIG. 6).

Initial structure 200 may be formed using any now known or later developed semiconductor fabrication techniques including by not limited to photolithography (and/or sidewall image transfer (SIT)). In lithography (or “photolithography”), a radiation sensitive “resist” coating is formed, e.g., deposited, over one or more layers which are to be treated, in some manner, such as to be selectively doped and/or to have a pattern transferred thereto. The resist, which is sometimes referred to as a photoresist, is itself first patterned by exposing it to radiation, where the radiation (selectively) passes through an intervening mask or template containing the pattern. As a result, the exposed or unexposed areas of the resist coating become more or less soluble, depending on the type of photoresist used. A developer is then used to remove the more soluble areas of the resist leaving a patterned resist. The patterned resist can then serve as a mask for the underlying layers which can then be selectively treated, such as to receive dopants and/or to undergo etching, for example.

Substrate 204 may include but is not limited to silicon, germanium, silicon germanium, silicon carbide, and those consisting essentially of one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable substrates include II-VI compound semiconductors having a composition Zn_{A1}Cd_{A2}Se_{B1}Te_{B2}, where A1, A2, B1, and B2 are relative proportions each greater than or equal to zero and A1+A2+B1+B2=1 (1 being a total mole quantity). Furthermore, a portion or entirety of each layer may be strained.

Fins 202 may be formed from substrate 204, for example, by epitaxial growth or etching from substrate 204. “Epitaxy” or “epitaxial growth,” as used herein, refers to a process by which a thin layer of single-crystal or large-grain polycrystalline material is deposited on a base material with similar crystalline properties. Etching generally refers to the removal of material from a substrate (or structures formed on the substrate), and is often performed with a mask in place so that material may selectively be removed from certain areas of the substrate, while leaving the material unaffected, in other areas of the substrate. There are generally two categories of etching, (i) wet etch and (ii) dry etch. Wet etch is performed with a solvent (such as an acid) which may be chosen for its ability to selectively dissolve a given material (such as oxide), while, leaving another material (such as polysilicon) relatively intact. This ability to selectively etch given materials is fundamental to many semiconductor fabrication processes. A wet etch will generally etch a homogeneous material (e.g., oxide) isotropically, but a wet etch may also etch single-crystal materials (e.g., silicon wafers) anisotropically. Dry etch may be performed using a plasma. Plasma systems can operate in several modes by adjusting the parameters of the plasma. Ordinary plasma etching produces energetic free radicals, neutrally charged, that react at the surface of the wafer. Since neutral particles attack the wafer from all angles, this process is isotropic. Ion milling, or sputter etching, bombards the wafer with energetic ions of noble gases which approach the wafer approximately from one direction, and therefore this process is highly anisotropic. Reactive-ion etching (RIE) operates under conditions intermediate between sputter and plasma etching and may be used to produce deep, narrow features, such as STI trenches. For example, trenches 206 may be formed in substrate 204, for example, by etching (e.g., by RIE).

Pad layer 210 may be formed, for example, by deposition using a mask (not shown) on substrate 204 before trenches 206 are formed. Where materials are deposited, “depositing” may include, unless otherwise stated, any now known or later developed techniques appropriate for the material to be deposited including but not limited to: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation. Pad layer 210 may include any now known or later developed materials for a barrier layer. For example, pad layer 210 may include a pad nitride layer or a pad oxide layer. In the non-limiting example of FIG. 2, pad layer 210 may include a pad nitride layer, for example, silicon nitride and/or any other now known or later developed nitride barrier material.

Liners 208 may be formed, for example, by deposition and/or any other now known or later developed technique for forming a liner in a trench. Liners 208 may include an oxide, and/or any other material for lining the trench of an STI.

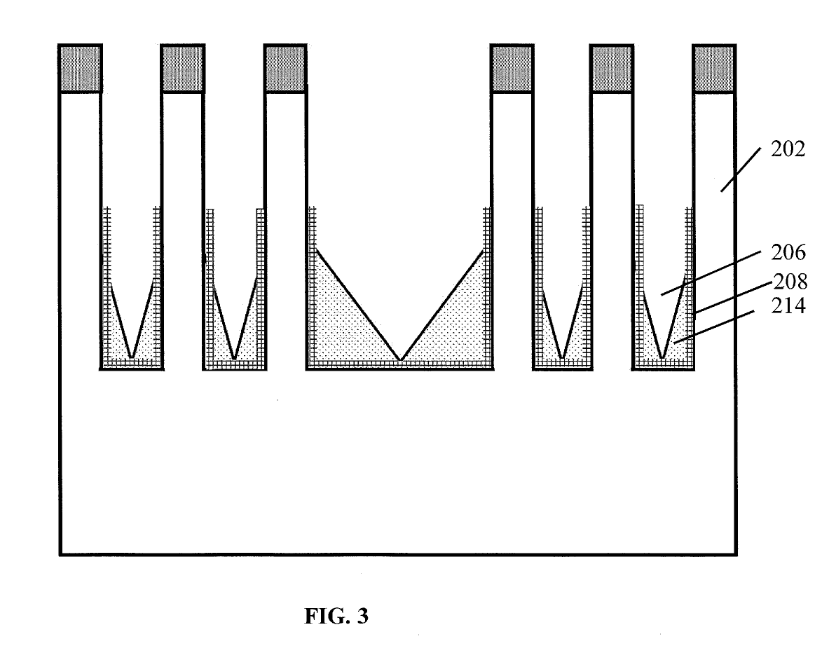

FIGS. 3-6 show forming STIs 220 (see FIG. 6) of semiconductor structure 230 (see FIG. 6), according to embodiments of the disclosure. Forming STIs 220 (see FIG. 6) according to embodiments of the disclosure may mitigate and/or prevent fins 202 from bending during formation and processing of the STI.

FIG. 3 shows forming first insulator layer 214 in trenches 206 on liners 208 of initial structure 200 (see FIG. 2) for STIs 220 (see FIG. 6), according to embodiments of the disclosure. In contrast to conventional STI formation, first insulator layer 214 may be formed by a bottom-up atomic layer deposition (ALD) process. As referred to herein, a bottom-up process may include a process of building larger structures of an integrated circuit (IC) from smaller structures such as, for example, an individual atom or molecule. A bottom-up process is in contrast to a top-down process which may include forming a smaller structure by providing a larger structure and removing a portion of the larger structure not needed to form the smaller structure. As referred to herein, ALD is a thin film deposition technique which may include cyclical or alternating exposure of a surface of a substrate to multiple precursor chemicals configured to react with the surface to build up a thin film on the surface. In contrast to conventional CVD processes, the surface is exposed to each precursor in separate, non-overlapping pulses, each exposure having its own self-limiting surface-precursor reaction. Therefore, forming first insulator layer 214 by a bottom-up ALD process may include building up the first insulator layer from molecules using the alternating exposure technique of ALD.

First insulator layer 214 may include, for example, silicon oxide and/or any other desirable materials for filling STIs 220 (see FIG. 6). Although FIG. 3 shows first insulator layer 214 as including a substantially V-shaped cross-sectional deposition geometry, first insulator layer 214 may be formed to include any cross-sectional deposition geometry. For example, although not shown, first insulator layer 214 may include, for example, a substantially U-shaped, substantially planar, etc., cross-sectional deposition geometry.

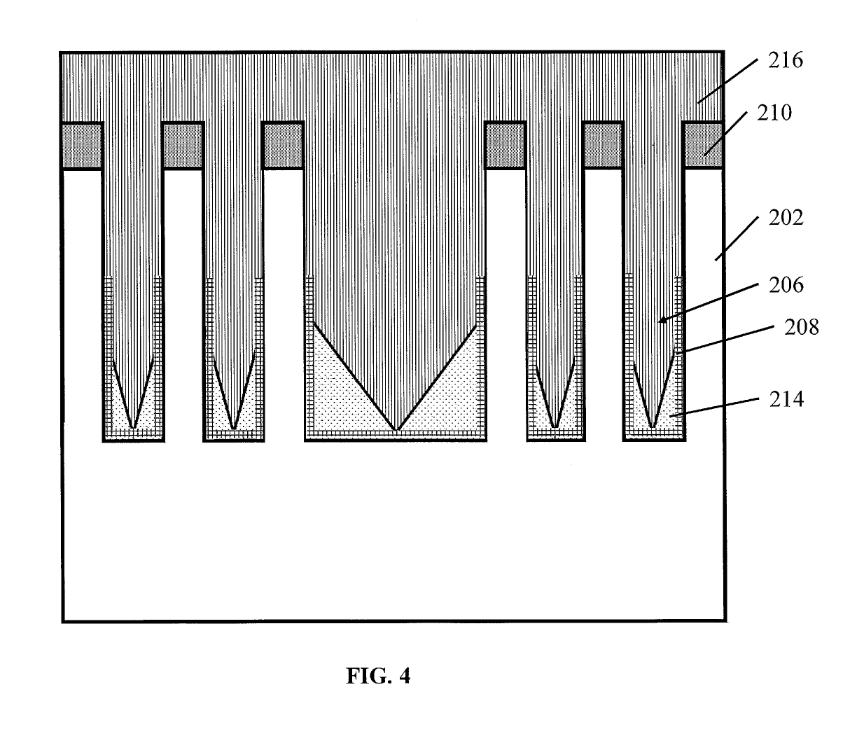

FIG. 4 shows forming a second insulator layer 216 in trenches 206 for STIs 220 (see FIG. 6), according to embodiments of the disclosure. In contrast to conventional STI formation, an etching step is not required between forming first insulator layer 214 and second insulator layer 216. As shown in the example of FIG. 4, second insulator layer 216 may be formed on first insulator layer 214 and a portion of liners 208.

Second insulator layer 216, may be formed to have any desirable thickness for an STI (e.g., STIs 220 of FIG. 6). As shown in the example of FIG. 4, second insulator layer 216 may be formed, in trenches 206, and above pad layer 210. In another example, not shown, second insulator layer 216 may be formed so that an upper surface 406 of the second insulator layer is positioned below an upper surface 408 of fins 202.

Second insulator layer 216 may be formed by CVD (FCVD, HDP, HARP, etc.) and/or any other now known or later developed semiconductor manufacturing techniques for forming an insulator layer in a trench. In the examples of FIGS. 3-6, second insulator layer 216 may be formed, for example, by FCVD. Second insulator layer 216 may include, for example, an oxide, and/or any desirable insulating material for an STI fill. Second insulator layer 216 may include a different density than first insulator layer 214, the density dependent on the deposition processed used to form the second insulator layer.

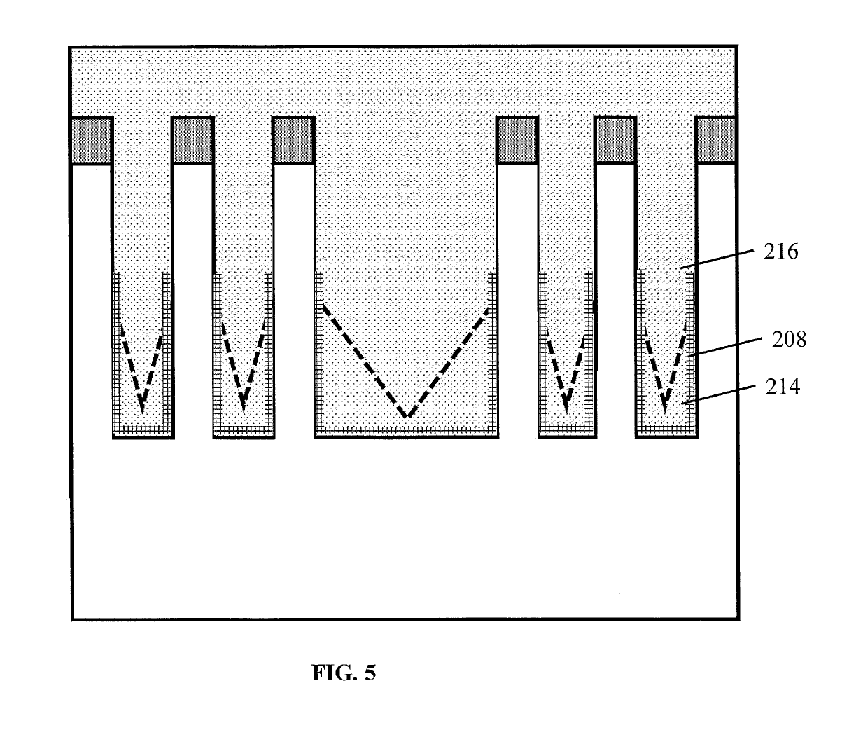

FIG. 5 shows processing first insulator layer 214 and second insulator layer 216 (see FIG. 4) for forming STIs 220 (see FIG. 6), according to embodiments of the disclosure. Insulator layers (e.g., second insulator layer 216 of FIG. 4) may require additional processing based on the type of deposition process utilized, in order to achieve desirable properties of the insulator layer for the STI. For example, where second insulator layer 216 (see FIG. 4) includes an oxide layer formed by FCVD, an anneal process may be performed on the insulator layers in an oxidizing ambient to densify second insulator layer 216 (see FIG. 4) to a silicon oxide (SiO₂) layer 218. The anneal process may include, for example, a steam anneal and/or ultraviolet cure (UV) process at approximately 400 degrees Celsius (° C.) to approximately 800° C. at approximately atmospheric pressure (ATM) for approximately 30 minutes to approximately 3 hours.

In contrast to conventional STI formation, where an STI is formed according to embodiments of the disclosure to include a layer formed by bottom-up ALD, the insulator layer formed by the bottom-up ALD process (e.g., first insulator layer 214) may densify, for example, to a range of approximately 2.5 g/cm³ of insulator material to approximately 3.0 g/cm³ of insulator material after annealing. The insulator layer may contract less than a conventionally formed insulator layer, for example, by approximately 5%, and the bending of fins 202 of semiconductor structure 230 (see FIG. 6) may be mitigated and/or prevented. In the example of FIG. 5, where first insulator layer 214 is formed by bottom-up ALD, and second insulator layer 216 is formed by FCVD, fins 202 may bend less than conventional processes, for example, by approximately 0.8 nanometers. Additionally, forming STIs 220 according to embodiments of the disclosure may also reduce the wet etch rate of the STIs. For example, where STI 220 is formed according to embodiments of the disclosure, the wet etch rate may be approximately 25 Å/min to approximately 35 Å/min compared to the approximately 35 Å/min to approximately 50 Å/min of an STI formed by conventional methods discussed above in the background.

As shown in FIG. 6, once first insulator layer 214 (see FIG. 3) and second insulator layer 216 (see FIG. 4) have been formed and processed, semiconductor structure 230 (see FIG. 6) may be further processed using conventional semiconductor manufacturing techniques to form STIs 220. For example, where second insulator layer 216 (see FIG. 4) is formed on fins 202, the formation of STIs 220 may further include exposing a portion 222 of fins 202. Portion 222 of fins 202 may be exposed, for example, by any now known or later developed semiconductor manufacturing techniques for removing a portion of second insulator layer 216 (see FIG. 4) after, for example, annealing (e.g., SiO₂ layer 218). For example, as shown in phantom in the example of FIG. 6, a first portion 226 of SiO₂ layer 218 may be removed to an upper surface 224 of pad layer 210. First portion 226 of SiO₂ layer 218 may be removed, for example, by chemical mechanical polishing (CMP). As shown in the example of FIG. 6, a second portion 228 of SiO₂ layer 218 and pad layer 210 may be removed to expose portion 222 of fins 202. For example, pad layer 210 may be removed by etching (e.g., RIE) and/or any other now known or later developed semiconductor manufacturing techniques for removing a pad layer. Second portion 228 of SiO₂ layer 218 may be removed, for example, by etching (e.g., RIE) to expose portion 222 of fins 202. As shown in FIG. 6, forming STIs 220 as described herein may mitigate and/or prevent the bending of fins 202 in semiconductor structure 230.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

1. A method of forming an integrated circuit (IC) structure, the method comprising:
providing an initial structure having: a substrate; a plurality of fins extending from the substrate; and a trench in the substrate isolating neighboring ones of the plurality of fins from one another,
forming a first insulator layer in a first portion of the trench in the substrate by a bottom-up atomic layer deposition (ALD) process,
wherein forming the first insulator layer by the ALD process includes forming the first insulator layer in a substantially V-shaped cross-sectional geometry or a substantially U-shaped cross-sectional geometry in the trench, and wherein the first insulator layer only partially fills the trench during the ALD process;
forming a second insulator layer directly on the first insulator layer in a second portion of the trench,
wherein forming the second insulator layer directly on the first insulator layer in the trench includes filling a gap in the substantially V-shaped cross-sectional geometry or the substantially U-shaped cross-sectional geometry in the trench; and
annealing the first insulator layer and the second insulator layer,
wherein the annealing densifies the first insulator layer to a range of approximately 2.5 g/cm³ of insulator material to approximately 3.0 g/cm³ of insulator material after the annealing.

2. The method of claim 1, further comprising forming an oxide liner in the trench before forming the first insulator layer.

3. The method of claim 1, further comprising forming a pad layer on a surface of the plurality of fins before forming the first insulator layer, wherein forming the second insulator includes forming the second insulator layer to fill the second portion of the trench and extend above the pad layer, wherein the trench is positioned between a pair of fins in the substrate.

4. (canceled)

5. (canceled)

6. The method of claim 1, wherein the annealing the second insulator layer includes steam annealing.

7. The method of claim 1, further comprising exposing a portion of the plurality of fins after the annealing the second insulator layer, wherein exposing the portion of the plurality of fins includes removing the pad layer and a portion of the second insulator layer.

8. (canceled)

9. The method of claim 1, wherein forming the second insulator layer includes using a flowable chemical vapor deposition (FCVD) process to deposit the second insulator layer.

10. The method of claim 1, wherein forming the second insulator layer includes using a high aspect ratio process (HARP) to deposit the second insulator layer.

11. The method of claim 1, wherein forming the second insulator layer includes using a high-density plasma chemical vapor deposition (HDP CVD) process to deposit the second insulator layer.

12. The method of claim 1, wherein the first insulator layer includes an oxide layer.

13. (canceled)

14. The method of claim 1, wherein a thickness of the first insulator layer is approximately 10 nanometers to approximately 100 nanometers.

15. A method of forming a shallow-trench-isolation (STI) in an integrated circuit (IC) structure, the method comprising:
forming an oxide liner in a trench in a substrate, the trench positioned between a set of fins in the substrate;
forming a first insulator layer on the oxide liner in a first portion of the trench by a bottom-up atomic layer deposition (ALD) process,
wherein forming the first insulator layer by the ALD process includes forming the first insulator layer in a substantially V-shaped cross-sectional geometry or a substantially U-shaped cross-sectional geometry in the trench, wherein the first insulator layer only partially fills the trench during the ALD process;
forming a second insulator layer on the first insulator layer in a second portion of the trench, wherein the second insulator layer covers the set of fins,
wherein forming the second insulator layer directly on the first insulator layer in the trench includes filling a gap in the substantially V-shaped cross-sectional geometry or the substantially U-shaped cross-sectional geometry in the trench;
annealing the first insulator layer and the second insulator layer,
wherein the annealing densifies the first insulator layer to a range of approximately 2.5 g/cm³ of insulator material to approximately 3.0 g/cm³ of insulator material after the annealing.

16. (canceled)

17. The method of claim 15, further comprising exposing a portion of the set of fins after the annealing the second insulator layer, the exposing including removing a portion of the second insulator layer covering the pair of fins.

18-20. (canceled)

21. The method of claim 1, wherein the first insulator layer contracts by approximately 5 percent or less during the annealing.

22. (canceled)

23. (canceled)

24. The method of claim 1, wherein the second insulator layer is formed directly on the first insulator layer without an intervening etch step.

25. The method of claim 15, wherein the first insulator layer contracts by approximately 5 percent or less during the annealing.

26. (canceled)

27. The method of claim 15, wherein the second insulator layer is formed directly on the first insulator layer without an intervening etch step.

28. The method of claim 15, further comprising forming a pad layer on a surface of the set of fins before forming the first insulator layer, wherein forming the second insulator includes forming the second insulator layer to fill the second portion of the trench and extend above the pad layer.

29. A method of forming an integrated circuit (IC) structure, the method comprising:
providing an initial structure having: a substrate; a plurality of fins extending from the substrate; and a trench in the substrate isolating neighboring ones of the plurality of fins from one another,
forming a first insulator layer in a first portion of the trench in the substrate by a bottom-up atomic layer deposition (ALD) process;
forming a second insulator layer directly on the first insulator layer in a second portion of the trench,
wherein the second insulator layer is formed directly on the first insulator layer without an intervening etch step; and
annealing the first insulator layer and the second insulator layer,
wherein the annealing densifies the first insulator layer to a range of approximately 2.5 g/cm³ of insulator material to approximately 3.0 g/cm³ of insulator material after the annealing.
